(19) United States
(12) Patent Application Publication
(10) Pub. No.: US 2010/0271564 A1
(43) Pub. Date: Oct. 28, 2010

(54) ACTIVE MATRIX SUBSTRATE, LIQUID CRYSTAL DISPLAY DEVICE HAVING THE SUBSTRATE, AND MANUFACTURING METHOD FOR THE ACTIVE MATRIX SUBSTRATE

(76) Inventor: Yukinobu Nakata, Osaka (JP)

Correspondence Address: BIRCH STEWART KOLASCH & BIRCH, PO BOX 747, FALLS CHURCH, VA, 22040-0747, US

(21) Appl. No.: 12/738,992

(22) PCT Filed: Sep. 16, 2008
(86) PCT No.: PCT/JP2008/066665

§ 371 Date: Apr. 21, 2010

(30) Foreign Application Priority Data
Dec. 20, 2007 (JP) 2007-328942

(51) Int. Cl. G02F 1/136; H01L 21/70; H01L 33/00

(52) U.S. Cl. 349/46; 438/34; 257/59; 257/E33.013; 257/E33.053; 257/E29.291; 257/E21.532

(57) ABSTRACT

The manufacturing method of the present invention is a manufacturing method for an active matrix substrate with use of photolithography. The method includes the steps of: (i) removing, in a region where each of terminal sections is to be formed in a non-display region (peripheral region), at least a part of a gate insulating film GI (first interlayer insulating layer) deposited on a gate metal film (first metal film), followed by depositing a source metal film (second metal film) so as to form a plurality of signal wirings (Step (2)); and (ii) etching, in a display region, a passivation film Pas (second interlayer insulating layer) deposited on a plurality of source wirings (signal wirings) and a semiconductor layer (i layer) formed into TFTs so that the passivation film Pas and the semiconductor layer (i layer) have a same pattern except a part of a drain electrode (16a) of each of the TFTs (Step (4)).

### TECHNICAL FIELD

The present invention relates to an active matrix substrate, a liquid crystal display device including the substrate, and a manufacturing method for the active matrix substrate.

### BACKGROUND ART

In recent years, liquid crystal display devices have been rapidly spreading due to their low power consumption and ease of downsizing in comparison with CRT (Cathode-Ray-Tube) display devices. Among the liquid crystal display devices, active matrix liquid crystal display devices are widely used, for they have a high response speed and are capable of easily displaying in multiple gray scales.

An active matrix liquid crystal display device includes an active matrix substrate in which numerous pixels are arranged in a matrix manner, a counter substrate disposed so as to face the active matrix substrate, and a liquid crystal layer which is sandwiched therebetween and which serves as a display medium.

One example of manufacturing methods for an active matrix substrate constituting an active matrix liquid crystal display device is a method, as described below, in which six photolithography steps (patterning steps) are carried out with the use of six photo masks.

This method includes the steps of: (1) performing patterning so as to form a gate, an auxiliary capacitor electrode, an auxiliary capacitor wiring, and the like; (2) forming a pattern of a semiconductor layer; (3) performing patterning on a gate insulating film that serves as a first interlayer insulating layer; (4) forming a pixel electrode; (5) forming source and drain electrodes; and (6) performing patterning on a passivation film that serves as a second interlayer insulating layer.

Thus, the conventional manufacturing method requires as many as six photolithography steps. This has resulted in an increase of the number of fabrication steps, thereby causing an increase in costs and a decrease in yields.

As a solution to this problem, Patent Literature 1 proposes a manufacturing method for a liquid crystal display device which manufacturing method can improve yields by reducing the number of photolithography steps to five.

### Citation List

Patent Literature 1

Japanese Patent Application Publication, Tokukaihei No. 9-120083 A (Publication Date: May 6, 1997)

### SUMMARY OF INVENTION

Meanwhile, there have been increasing demands on recent liquid crystal display devices for a higher aperture ratio in a display region of a display panel.

In a case where an active matrix substrate is manufactured in accordance with the manufacturing method disclosed in Patent Literature 1, a double-layered interlayer insulating film constituted by the gate insulating layer and the passivation film is formed between the pixel electrode and the auxiliary capacitor electrode made of a gate metal film. This causes an increase in the distance between the pixel electrode and the auxiliary capacitor electrode, thereby resulting in that capacitance efficiency per area decreases. Nevertheless, enlarging the area of the auxiliary capacitor electrode section in order to ensure a necessary capacitance leads to a problem of a decrease in the aperture ratio of the pixel electrode.

As such, for a further increase in the aperture ratio of the liquid crystal display device, the manufacturing method disclosed in Patent Literature 1 is disadvantageous.

Moreover, in order to downsize a liquid crystal display device, it is required that a non-display region (frame region), which is provided on a periphery of the display region, has a smallest possible area. However, there are cases where a terminal for electrically connecting a source wiring and a gate wiring with each other are provided in the non-display region so that these wirings are used as prewirings (redundant wirings) or the like. In such cases, in the active matrix substrate obtained by the manufacturing method disclosed in Patent Literature 1, restrictions of manufacturing steps make it impossible to directly connect the source wiring to the gate wiring. That is, it is necessary to interpose a conductive material such as a pixel electrode material between the source wiring and the gate wiring. Consequently, a problem arises that the area of the frame region ends up being large.

The present invention is accomplished in view of the above problems, and an object of the present invention is to attain an increase in aperture ratio and a decrease in frame region in a liquid crystal display device including an active matrix substrate, in a case where the active matrix substrate is manufactured through five or less photolithography steps.

In order to achieve the above object, a manufacturing method for an active matrix substrate according to the present invention is a method for manufacturing an active matrix substrate of a display device, the method includes forming a pattern by photolithography, which active matrix substrate includes: a plurality of scan wirings made of a first metal film; a plurality of signal wirings made of a second metal film, provided so as to intersect the plurality of scan wirings; TFTs provided in a vicinity of respective intersections of the plurality of scan wirings and the plurality of signal wirings; pixel electrodes each connected to a corresponding TFT; auxiliary capacitor electrodes made of the first metal film, provided so as to form auxiliary capacitances in cooperation with corresponding pixel electrodes therebetween; and terminal sections provided in a peripheral region provided on a periphery of a display region of the display device, and the method of the present invention includes the steps of: (i) removing, in a region where each of the terminal sections is to be formed, at least a part of a first interlayer insulating layer deposited on a first metal film, followed by depositing a second metal film so as to form the plurality of signal wirings; and (ii) etching, in the display region, a second interlayer insulating layer deposited on the plurality of signal wirings and a semiconductor layer formed into the TFTs so that the second interlayer insulating layer and the semiconductor layer have a same pattern except a part of a drain section of the TFTs.

According to the above-described method, at the time of forming the second metal film, at least a part of the first interlayer insulating layer deposited on the first metal film has been removed so that the first metal film is exposed. This makes it possible to bring the first metal film and the second metal film into direct contact so as to be electrically connected with each other. As such, with the manufacturing method of the present invention, in a case where an active matrix substrate is manufactured through a plurality of photolithography steps, a contact size between the first metal film and the second metal film can be decreased in comparison with a conventional arrangement that has no other alternative but to electrically connect the first metal film and the second metal film with a conductive material, such as a pixel electrode material, being provided therebetween.

Furthermore, in the above-described method, the second interlayer insulating layer and the semiconductor layer formed into the TFT are etched in the display region so that the second interlayer insulating layer and the semiconductor layer have a same pattern except a part of a drain section of each of the TFTs. Consequently, only the first interlayer insulating layer is provided between the auxiliary capacitor electrode made of the first metal film and the pixel electrode. This makes it possible to decrease the distance between the auxiliary capacitor electrode and the pixel electrode, thereby improving the capacitance efficiency per area. As a result, the area of the auxiliary capacitor electrode can be decreased in comparison with that in the conventional arrangement. Consequently, it is possible to curb a decrease in the aperture ratio of the pixel electrode.

The manufacturing method according to the present invention for manufacturing an active matrix substrate may include the steps of: (a) performing patterning on the first metal film deposited on an insulating substrate so as to form the plurality of scan wirings; (b) depositing the first interlayer insulating layer and then the semiconductor layer on the plurality of scan wirings and then performing patterning, by etching, on the first interlayer insulating layer and the semiconductor layer in the region where the each of the terminal sections is to be formed, so as to form the each of the terminal sections; (c) depositing the second metal film on the semiconductor layer and then performing patterning, by etching, on the second metal film and the semiconductor layer so as to form the plurality of signal wirings; (d) depositing the second interlayer insulating layer on the plurality of signal wirings and then performing patterning on the second interlayer insulating layer and the semiconductor layer in a predetermined shape; and (e) depositing, after the step (d), a transparent conductive material film and then etching the transparent conductive material film so as to form the pixel electrodes.

With the use of an active matrix substrate obtained in accordance with the above-described manufacturing method, it is possible to attain an increase in aperture ratio and a decrease in frame region in a liquid crystal display device.

In the meantime, according to the manufacturing method of Patent Literature 1, as shown in (a) and (b) of FIG. 14, patterning is performed in such a manner that a semiconductor layer (n⁺ layer and i layer) is left in a display region of an active matrix substrate so as to cover a part of a gate electrode, but entirely removed elsewhere.

In contrast, in the manufacturing method of the present invention for manufacturing an active matrix substrate, in the step (b), after the first interlayer insulating layer and the semiconductor layer have been deposited, the first interlayer insulating layer and the semiconductor layer are left unetched in the display region, while the first interlayer insulating layer and the semiconductor layer are patterned by etching in the region where the each of the terminal sections is to be formed.

Furthermore, in order to achieve the above object, an active matrix substrate according to the present invention is an active matrix substrate included in a display device, including: a plurality of scan wirings made of a first metal film; a plurality of signal wirings made of a second metal film, provided so as to intersect the plurality of scan wirings; TFTs provided in a vicinity of respective intersections of the plurality of scan wirings and the plurality of signal wirings; pixel electrodes each connected to a corresponding TFT; and terminal sections provided in a peripheral region provided on a periphery of a display region of the display device, and each of the TFTs includes: a first interlayer insulating layer and a semiconductor layer, which are deposited on a gate electrode in this order; a source electrode and a drain electrode, each provided on the semiconductor layer; and a second interlayer insulating layer provided on the source electrode and the drain electrode, the semiconductor layer including an impurity-undoped i layer and an impurity-doped n⁺ layer, and the second interlayer insulating layer and the i layer being provided so as to have a same pattern except a part of a region where the drain electrode is provided, and each of the terminal sections is arranged such that a contact hole is provided in a same shape in the first interlayer insulating layer and the semiconductor layer so that the first metal film has direct contact with the second metal film via the contact hole so that they are electrically connected with each other.

In the above-described arrangement, the i layer, which constitutes the semiconductor layer, is provided so as to have the same pattern as the pattern of the second interlayer insulating layer except a part of a drain section of the TFT.

In addition, unlike the conventional technique, the above-described arrangement eliminates the need for connecting the source wiring to the gate wiring via the pixel electrode (ITO) or the like, thereby resulting in that the source wiring and the gate wiring can directly contact with each other. This arrangement makes it possible to decrease the contact size and the area of the frame region.

The active matrix substrate of the present invention further includes: auxiliary capacitor electrodes made of the first metal film, provided so as to form auxiliary capacitances in cooperation with corresponding pixel electrodes therebetween, and the auxiliary capacitor electrodes are arranged such that only the first interlayer insulating layer is provided between the auxiliary capacitor electrodes and the corresponding pixel electrodes, thereby causing the auxiliary capacitances to be formed therebetween.

With the above-described arrangement, it is possible to improve capacitance efficiency per area in comparison with the conventional arrangement having a double-layered structure of a passivation film and a gate insulating film between the pixel electrode and the auxiliary capacitor electrode. This arrangement can decrease the auxiliary capacitor electrode in area, thereby achieving a higher aperture ratio of the pixel electrode.

The liquid crystal display device according to the present invention includes: any of the foregoing active matrix substrates; a counter substrate; and a liquid crystal layer sandwiched between the active matrix substrate and the counter substrate.

Since the liquid crystal display device of the present invention includes any of the foregoing active matrix substrates, it is possible to attain an increase in aperture ratio and a decrease in frame region.

For a fuller understanding of the nature and advantages of the invention, reference should be made to the ensuing detailed description taken in conjunction with the accompanying drawings.

### BRIEF DESCRIPTION OF DRAWINGS

FIG. 1 is a group of schematic views illustrating manufacturing steps of an active matrix substrate according to an embodiment of the present invention.

FIG. 2 is a plan view illustrating a part of an active matrix substrate provided in a liquid crystal display device according to the present embodiment.

FIG. 3 is a group of plan views illustrating manufacturing steps of the active matrix substrate illustrated in FIG. 2 in sequence.

FIG. 4 is a group of cross sectional views illustrating manufacturing steps of the active matrix substrate illustrated in FIG. 2 in sequence. FIG. 4 shows cross sectional structures of the active matrix substrate taken along the line A-A′ of FIG. 2.

FIG. 5 is a group of cross sectional views illustrating manufacturing steps of the active matrix substrate illustrated in FIG. 2 in sequence. FIG. 5 shows cross sectional structures of the active matrix substrate taken along the line B-B′ of FIG. 2

FIG. 6 is a group of cross sectional views and plan views illustrating manufacturing steps of the active matrix substrate illustrated in FIG. 2 in sequence. FIG. 6 shows cross sectional structures and plane structures of the active matrix substrate.

FIG. 7 is a view illustrating a cross sectional structure of the active matrix substrate taken along the line A-A′ of FIG. 2.

FIG. 8 is a view illustrating a cross sectional structure of the active matrix substrate taken along the line B-B′ of FIG. 2.

FIG. 9

(a) of FIG. 9 is a cross sectional view illustrating a structure of a terminal section arranged on a peripheral region (frame region) of an active matrix substrate included in a liquid crystal display device according to the embodiment. (b) of FIG. 9 is a plan view illustrating a structure of the terminal section.

FIG. 10

(a) of FIG. 10 is a cross sectional view illustrating a wiring connection section provided on a peripheral region (frame region) of an active matrix substrate included in a liquid crystal display device according to the present embodiment. (b) of FIG. 10 is a plan view illustrating a structure of the wiring connection section.

FIG. 11 is a group of schematic views illustrating manufacturing steps of a conventional active matrix substrate.

FIG. 12 is a cross sectional view illustrating a structure of an auxiliary capacitor section in an active matrix substrate manufactured through the manufacturing steps illustrated in FIG. 11.

FIG. 13 is a cross sectional view illustrating a contact structure of how a source wiring (source metal film) is connected to a gate wiring (gate metal film) in an active matrix substrate manufactured through the manufacturing steps illustrated in FIG. 11.

FIG. 14

(a) of FIG. 14 is a plan view partially illustrating an arrangement of the substrate that has been patterned through the photolithography steps of (2) of FIG. 11. (b) of FIG. 14 is a cross sectional view illustrating a structure taken along the line A-A′ of FIG. 14(a).

FIG. 15 is a cross sectional view illustrating a structure of a terminal section of the substrate patterned through the photolithography steps of (2) of FIG. 11.

### REFERENCE SIGNS LIST

10 Active Matrix Substrate

11 Gate Wiring (Scan Wiring)

11a Gate Electrode

12 Source Wiring (Signal Wiring)

12a Source Electrode

13 Auxiliary Capacitor Wiring

13a Auxiliary Capacitor Electrode

14 Pixel Electrode

15 TFT

16a Drain Electrode

19 Terminal Section

19a Contact Hole, Aperture

21 Gate Insulating Film (First Interlayer Insulating Layer)

22 Semiconductor Layer

23 Passivation Film (Second Interlayer Insulating Layer)

25 Wiring Connection Section

25a Contact Hole

50 Resist

### DESCRIPTION OF EMBODIMENTS

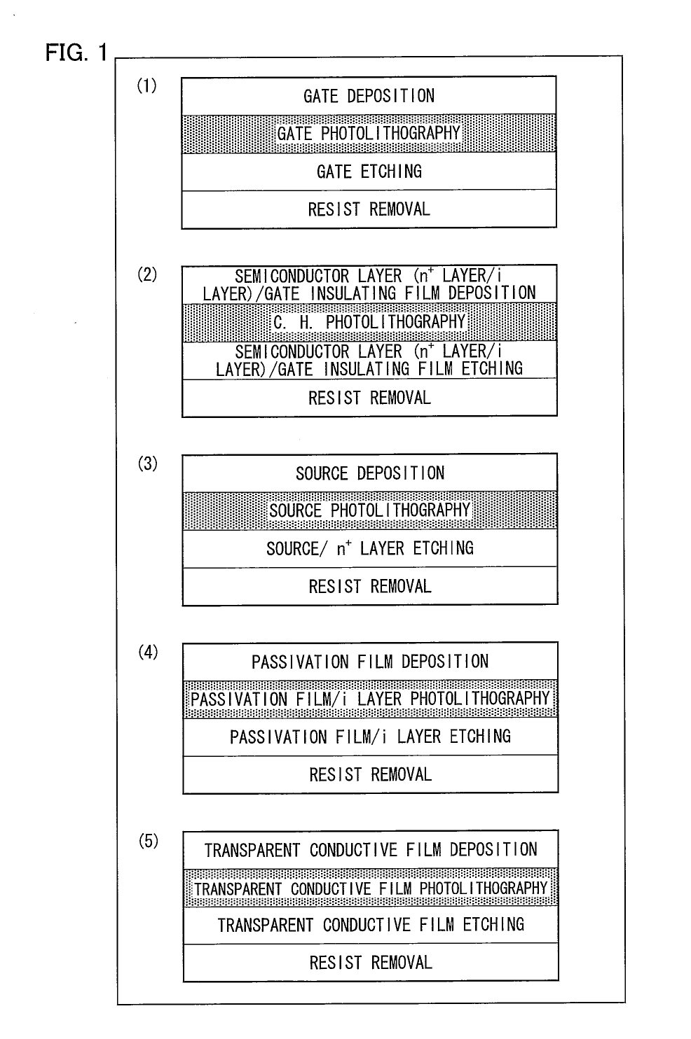

An embodiment of the present invention will hereinafter be described with reference to FIGS. 1 to 10. It is noted that the present invention is in no way limited thereto.

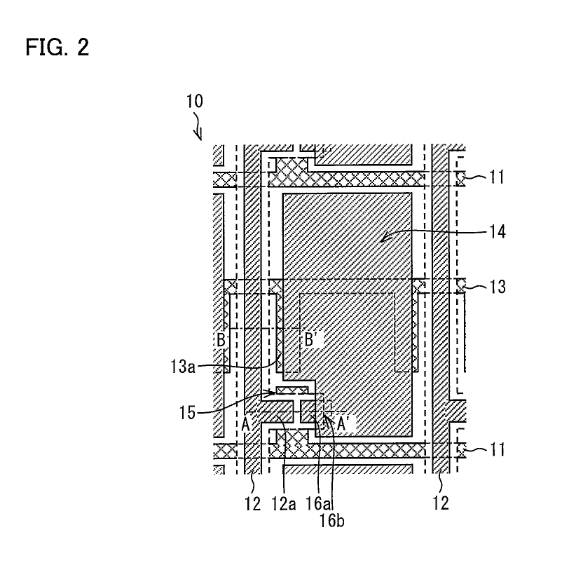

This embodiment describes an active matrix liquid crystal display device. FIG. 2 shows a part of an active matrix substrate 10 included in a liquid crystal display device according to the present embodiment.

The active matrix substrate 10 includes a plurality of gate wirings (scan wirings) 11 and a plurality of source wirings (signal wirings) 12 so that they intersect with each other. In the vicinity of each of the intersections thereof, a pixel section having a TFT (switching element) 15 is provided.

Specifically, on the active matrix substrate 10, as shown in FIG. 2, the plurality of gate wirings 11, which elongate parallel to each other in a lateral direction in the figure, are provided. Also, the plurality of source wirings 12, which elongate in a longitudinal direction in the figure, are provided so as to intersect the plurality of gate wirings 11. In addition, between any adjacent two of the plurality of gate wirings 11, an auxiliary capacitor wiring 13 is provided parallel to the gate wirings.

In the vicinity of an intersection of each of the gate wirings 11 and each of the source wirings 12, a TFT 15 is provided as a switching element that is electrically connected to the each of the gate wirings 11 and the each of the source wirings 12. A pixel electrode 14 is provided in a corresponding manner to the TFT 15. In response to an instruction on electrical conduction from a scanning signal that is inputted into the gate wiring 11, the TFT 15 connects the source wiring 12 to the pixel electrode 14 so that the data signal transmitted to the source wiring 12 is inputted into the pixel electrode 14.

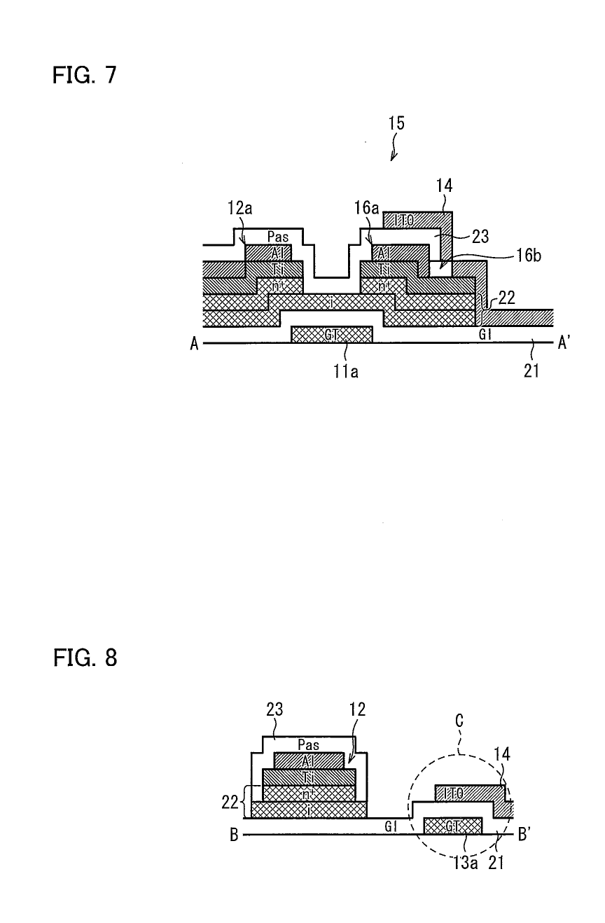

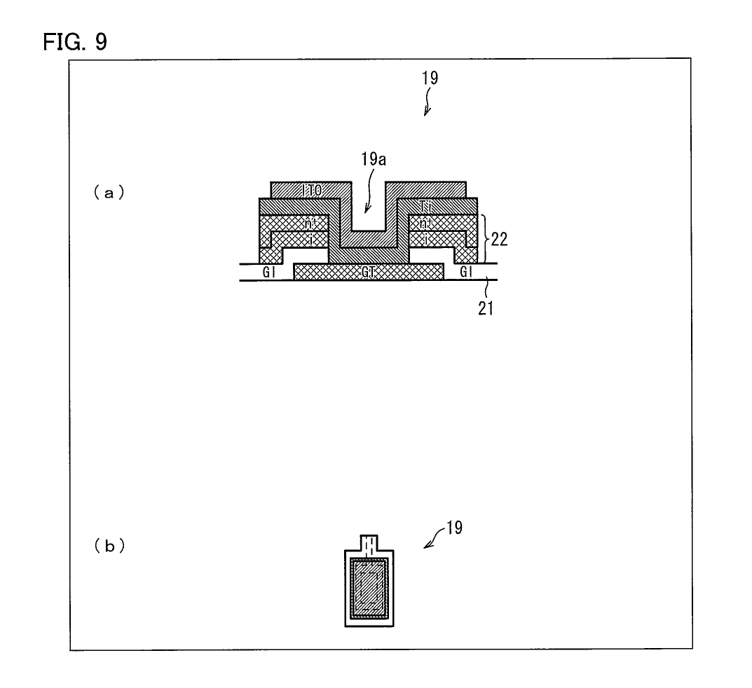

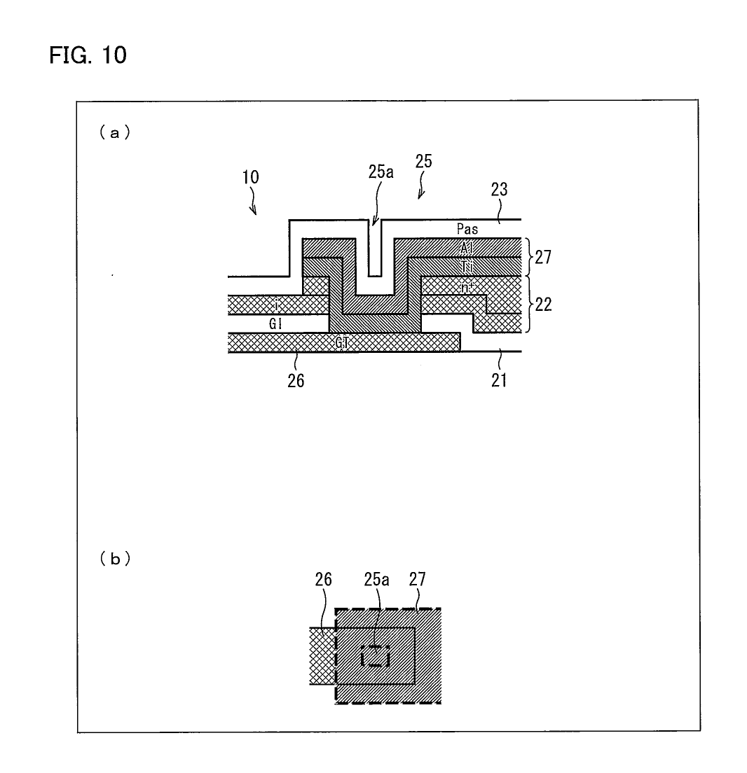

FIG. 7 shows a cross sectional structure of the vicinity of the TFT 15 (taken along the line A-A′ of FIG. 2) provided in the active matrix substrate 10. FIG. 8 shows a cross sectional structure of the vicinity of a source wiring 12 and an auxiliary capacitor electrode 13a (taken along the line B-B′ of FIG. 2) provided in the active matrix substrate 10. Although it is not illustrated in FIG. 2, the active matrix substrate 10 includes a display region and a non-display region. The display region (for example, the region shown in FIG. 2) is arranged such that pixel electrodes are provided in a matrix manner, and the display region displays an image that is observed by a viewer. Meanwhile, the non-display region (also referred to as “peripheral region” or “frame region”) is disposed outward (i.e., on a periphery of) the display region and displays an image that is not observed by the viewer. FIG. 9 shows a cross sectional structure and a plane structure of a terminal section 19 provided in the non-display region of the active matrix substrate 10. FIG. 10 shows a cross sectional structure and a plane structure of a wiring connection section 25 provided in the non-display region of the active matrix substrate 10.

As illustrated in FIGS. 2 and 7, the TFT 15 includes a gate electrode 11a, a gate insulating film (first interlayer insulating layer) 21, a semiconductor layer 22, a source electrode 12a, and a drain electrode (drain section) 16a, which are deposited on an insulating substrate (not illustrated) that serves as a base. The gate electrode 11a is made of the same material as that of the gate wiring 11 (i.e., a gate metal film). The source electrode 12a and the drain electrode 16a are made of the same material as that of the source wiring 12 (i.e., a source metal film). The semiconductor layer 22 is made up of an impurity-undoped amorphous silicon film (i layer) and an impurity-doped n⁺ amorphous silicon film (n⁺ layer). The gate electrode 11a is connected to the gate wiring 11, and the source electrode 12a is connected to the source wiring 12.

Deposited on the TFT 15 is a passivation film (second interlayer insulating layer) 23. Furthermore, on the passivation film 23, a transparent conductive film (IZO or ITO) is deposited so as to partly cover the drain electrode 16a. The transparent conductive film serves as the pixel electrode 14.

In the present embodiment, Ti/Al/Ti or the like can be used as a material of the gate metal film. Further, Al, Ti, or the like can be used as a material of the source metal film. In the example illustrated in FIG. 7, the source metal film is formed by depositing a Ti film and an Al film. The gate insulating film 21 and the passivation film 23 are made of a material such as silicon nitride. However, in the present invention, the materials are not necessarily limited to those mentioned above, and it is possible to use materials that have been conventionally used in common for an active matrix substrate.

As illustrated in FIGS. 2 and 8, in a region where the source wiring 12 is to be formed, the gate insulating layer 21 and the semiconductor layer 22 are deposited on the insulating substrate (not illustrated) that serves as a base. On the semiconductor layer 22 is deposited the source wiring 12 made of a source metal film. The source wiring 12 is covered with the passivation film 23 so that the source wiring 12 is protected by the passivation film 23.

A circled region C shown in FIG. 8 is a region where an auxiliary capacitance is formed. The auxiliary capacitance is formed between the auxiliary capacitor electrode 13a, which is formed of protrusion of the auxiliary capacitor wiring 13, and the pixel electrode 14, which is provided so as to face the auxiliary capacitor electrode 13a via the gate insulating film 21.

A terminal section 19 illustrated in (a) and (b) of FIG. 9 is used as a connection terminal to a liquid crystal driving circuit. A wiring connection section 25 illustrated in (a) and (b) of FIG. 10 is used as a connection section between wirings and the like in the peripheral region.

(a) of FIG. 9 illustrates a cross sectional structure of the terminal section 19. As illustrated in this figure, the terminal section 19 is structured by depositing, on an insulating substrate (not illustrated), a gate metal film, a gate insulating film, a semiconductor layer 22, a source metal film (here, only a Ti film), and a transparent conductive film. In a region where the gate metal film is provided, a contact hole 19a is partly provided so that the gate metal film and the source metal film are electrically connected via the contact hole 19a. The contact hole 19a is obtained by providing a hole in the same form in the gate insulating film and in the semiconductor layer (i layer and n⁺ layer) 22.

(a) of FIG. 10 illustrates a cross sectional structure of the wiring connection section 25. As illustrated in this figure, the cross sectional structure of the wiring connection section 25 is similar to the cross sectional structure of the terminal section 19 in that a gate metal film 26 and a source metal film 27 are electrically connected via a contact hole 25a.

The liquid crystal display device of the present embodiment includes an active matrix substrate having the above-described arrangement, a counter substrate provided with a color filter layer, counter electrodes, and the like and disposed so as to overlie the active matrix substrate, and a liquid crystal layer provided between these substrates.

Now, a manufacturing method for the active matrix substrate 10 having the above-described arrangement is described.

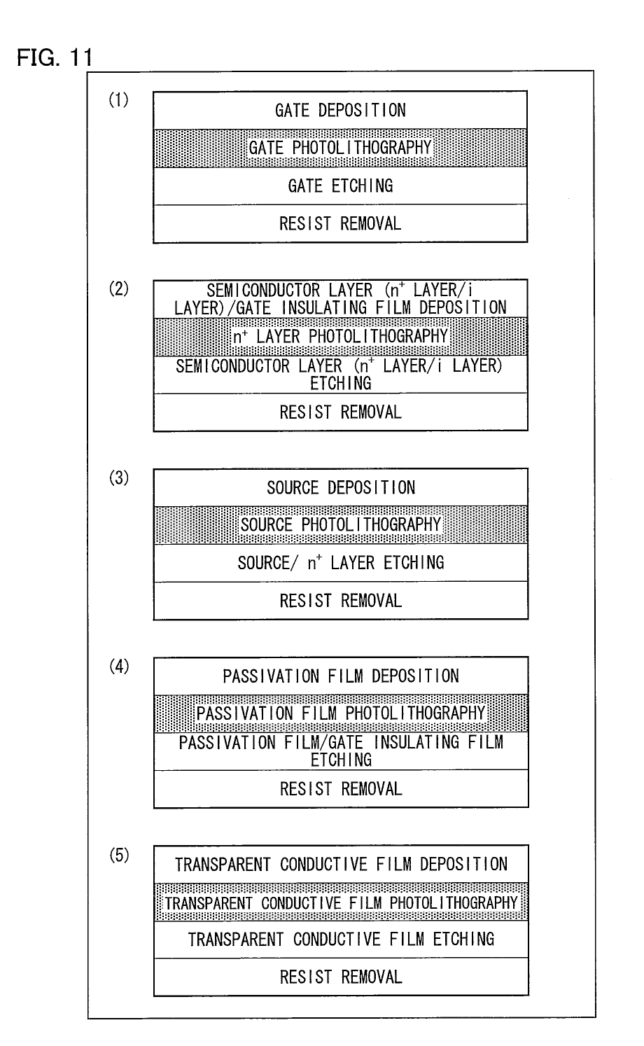

FIG. 1 shows the manufacturing method for the active matrix substrate 10 in the order of the steps. In this figure, respective photolithography steps are denoted by numerals (1) to (5). For the purpose of comparison, FIG. 11 shows the steps of a conventional method for manufacturing an active matrix substrate through five photolithography steps. It is noted that the manufacturing method shown in FIG. 11 accords with the manufacturing method described in Patent Literature 1.

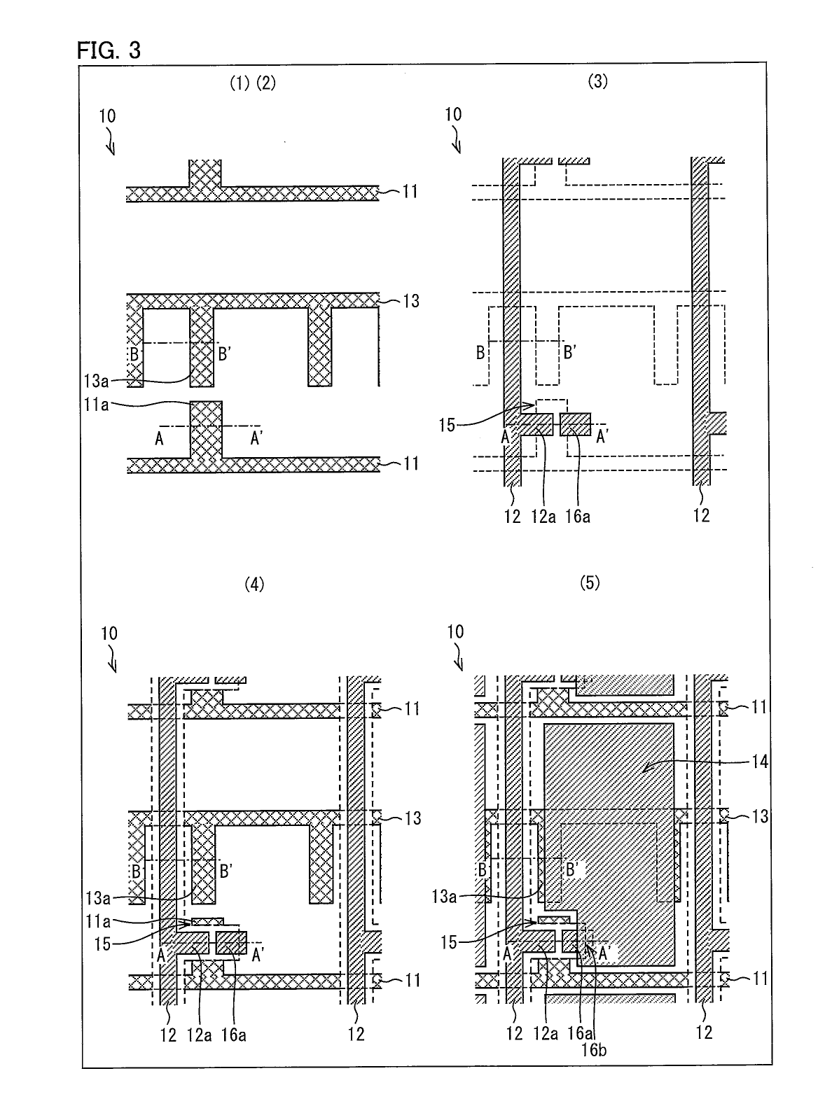

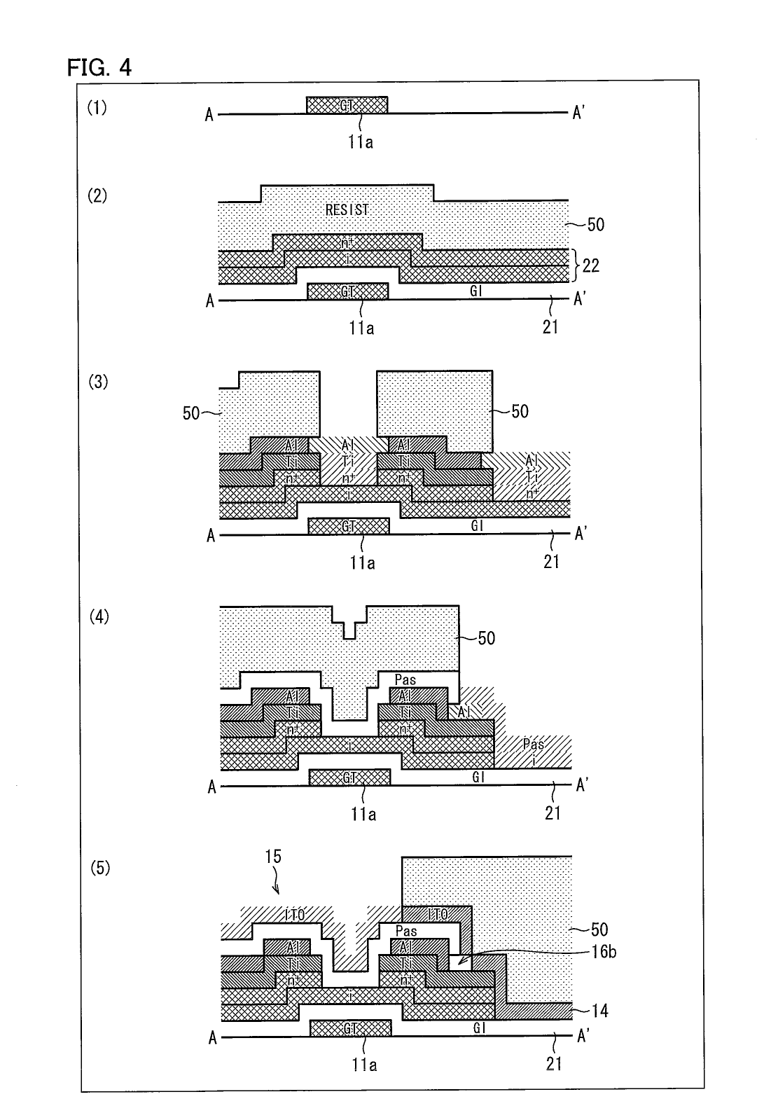

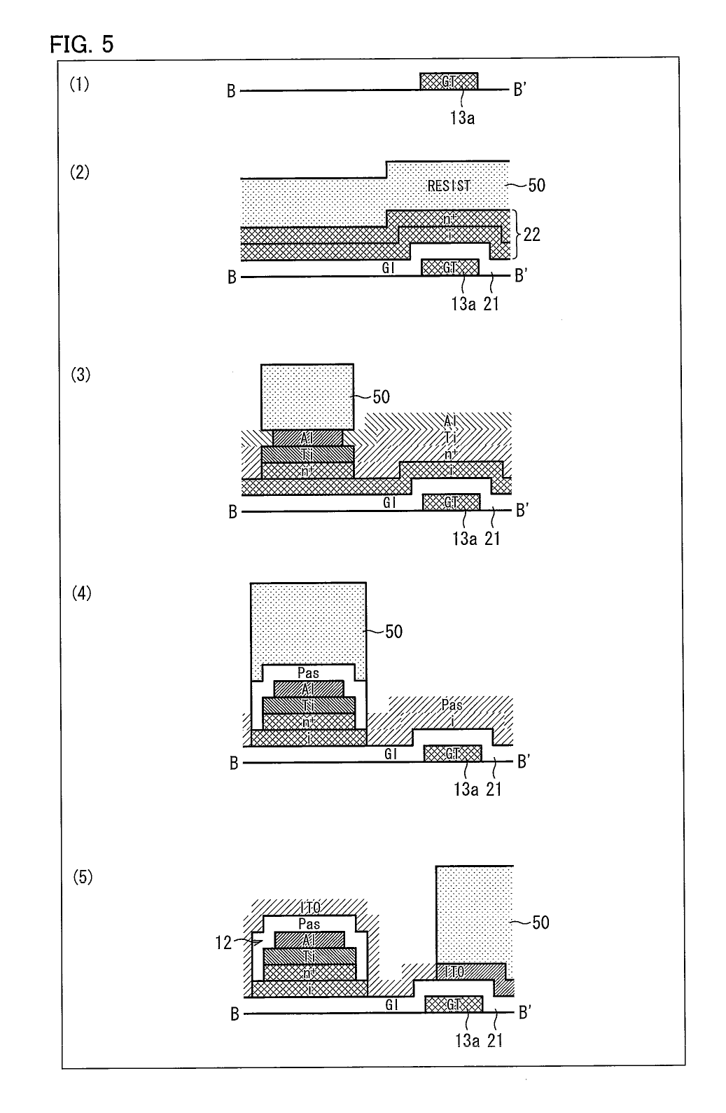

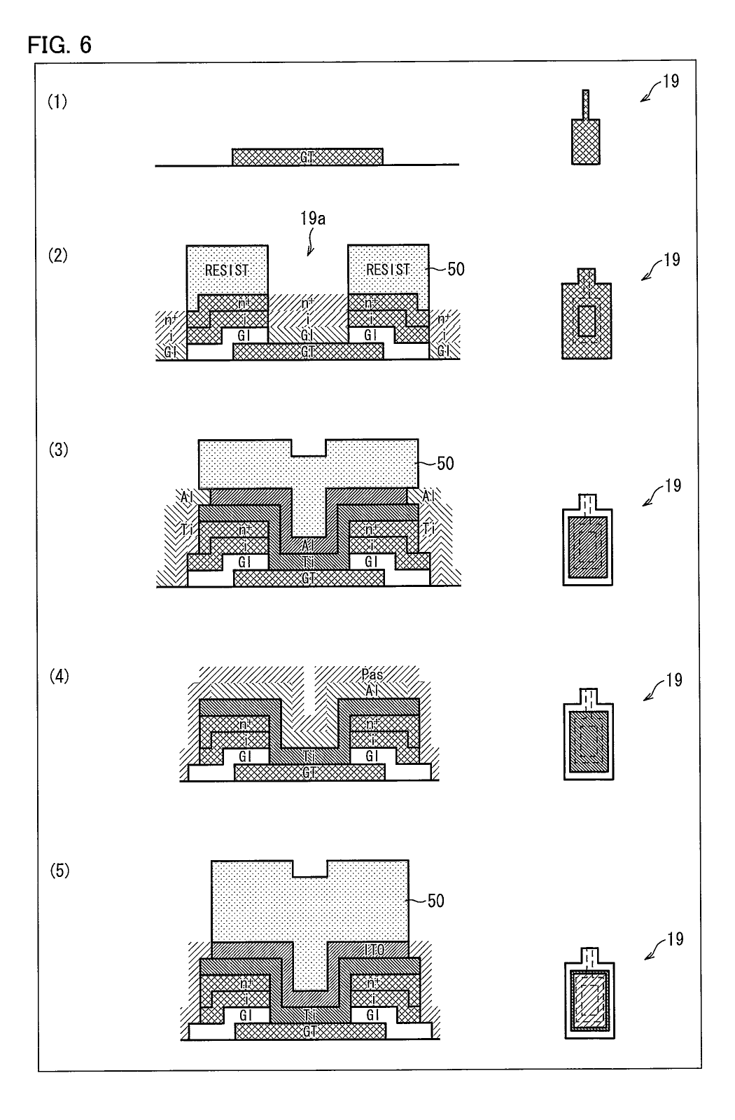

FIG. 3 illustrates plane structures of a part of the active matrix substrate 10, each upon completion of each photolithography step (1) to (5) shown in FIG. 1. FIG. 4 illustrates cross sectional structures of the vicinity of the TFT 15 of the active matrix substrate 10 (along the line A-A′ of FIG. 2), each upon completion of each photolithography step (1) to (5) shown in FIG. 1. FIG. 5 illustrates cross sectional structures of the vicinity of the source wiring 12 and the auxiliary capacitor electrode 13a of the active matrix substrate 10 (along the line B-B′ of FIG. 2), each upon completion of each photolithography step (1) to (5) shown in FIG. 1. FIG. 6 illustrates cross sectional structures and plane structures of the vicinity of the terminal section 19 of the active matrix substrate 10, each upon completion of each photolithography step (1) to (5) shown in FIG. 1.

Now, with reference to FIG. 1, the manufacturing method of the present invention is described in the order of the steps.

(1) First Photolithography Step

In a first photolithography step illustrated in (1) of FIG. 1, after a formation (deposition) of a gate metal film (GT) on an insulating substrate (not illustrated), a resist pattern is formed with use of a first photo mask (gate photolithography). Subsequently, a wiring pattern as shown in (1) of FIG. 3 is formed by dry-etching, and then the resist is removed. (1) of FIG. 4, (1) of FIG. 5, and (1) of FIG. 6 illustrate respectively the cross sectional structures taken along the lines A-A′ and B-B′ in FIG. 2 and a cross sectional structure of the terminal section 19 as of this moment.

(2) Second Photolithography Step

In a second photolithography step shown in (2) of FIG. 1, first, a semiconductor layer (i layer and n⁺ layer) and a gate insulating layer (GI) are successively deposited. Then, with use of a second photo mask, photolithography is carried out so as to form a pattern of the terminal section 19 (n⁺ layer photolithography).

The photo mask used in this step is configured in such a manner that a resist 50 is formed on the entire surface of the display region (refer to (2) of FIG. 4 and (2) of FIG. 5) except that an aperture is partly formed in the resist only at the part of the terminal section 19 ((2) of FIG. 6).

In the etching process, the semiconductor layer (i layer and n⁺ layer) and the gate insulating layer (GI), which have already been deposited, are entirely dry-etched and removed so that a surface of the gate metal film (GT) is exposed at an aperture section 19a of the resist (refer to (2) of FIG. 6).

It is noted that, in FIGS. 4, 5, and 6, areas to be etched and removed are represented by hatched lines with wider spacing.

(3) Third Photolithography Step

In a third photolithography steps shown in (3) of FIG. 1, first, a source metal film (a laminated film of a Ti layer and an Al layer) is deposited. Then, with use of a third photo mask, photolithography is performed mainly for forming a pattern on the source metal film (source photolithography).

In this step, a resist is patterned so as to separate the drain electrode 16a and the source electrode 12a of the TFT 15 (refer to (3) of FIG. 4). Moreover, along the line B-B′ of the active matrix substrate 10, the resist is patterned so as not to be formed in any other region than a region where the source wiring is to be formed (refer to (3) of FIG. 5). In the meantime, the resist is formed in a region where the terminal section 19 is formed (refer to (3) of FIG. 6).

Then, in a region other than the region where the resist has been formed, the Al layer of the source metal film is etched by first etching, followed by dry-etching the remaining Ti layer and the semiconductor layer (n⁺ layer) by second etching, so that these layers are removed. Then, the resist is removed.

Thus, a general pattern of a channel region of the TFT 15 is formed. At this point, the semiconductor layer (only the i layer) is left on the almost entire surface of a transparent region (a region where the pixel electrode and the like are formed) in the display region.

(4) Fourth Photolithography Step

In a fourth photolithography step shown in (4) of FIG. 1, first, a passivation film (Pas) is deposited. Then, with use of a fourth photo mask, photolithography is performed so that the passivation film is patterned in a predetermined shape (Pas/i photolithography). The passivation film serves as a protection film for the TFT 15, the source wiring 12, and the others.

In this step, a resist is patterned so that the passivation film is left on the TFT 15 (refer to (4) of FIG. 4). At the same time, however, the resist is patterned so that the passivation film is removed at a part of the source metal film (Ti layer) (a region 16b shown in FIGS. 2, 7, and the like). Moreover, the resist is patterned so as to be formed on the source wiring 12 (refer to (4) of FIG. 5). In the meantime, no resist is formed on the terminal section 19 (refer to (4) of FIG. 6).

Then, first etching is performed so that the passivation film (Pas) and the semiconductor layer (i layer) are removed (by successively dry-etching the Pas and the i layer). Subsequently, second etching is performed so that the source metal film (only the Al layer) is etched and removed. This results in that the Al layer left on the terminal section 19 is removed as well as the Al layer in the region 16b.

As described above, in the fourth photolithography step, after the passivation film has been deposited on the source wiring 12, the photolithography is performed in such a manner that, in the region where the TFT 15 is provided, the passivation film and the semiconductor layer (i layer) (i.e., the second interlayer insulating layer and the semiconductor layer that constitutes the TFT) are patterned in the same shape except a part of the drain electrode 16a (specifically, the region 16b provided on the passivation film) of the TFT 15.

(5) Fifth Photolithography Step

In a fifth photolithography step shown in (5) of FIG. 1, first, a film of a transparent conductive material, such as ITO (or IZO), is provided to form a pixel electrode 14. Then, with use of a fifth photo mask, photolithography is carried out so as to pattern the transparent conductive material in a predetermined shape (ITO photolithography).

A resist is formed in a region where the pixel electrode 14 is to be formed and a region where the terminal section 19 is to be formed. The pixel electrode 14 is formed so as to partly overlie the drain electrode 16a and be electrically connected to the drain electrode 16a through the region 16b.

Then, the transparent conductive material is etched and removed in a region other than the region where the resist has been formed. Consequently, as illustrated in (5) of FIG. 4 and (5) of FIG. 5, the pixel electrode 14 is formed. Here, as shown in (5) of FIG. 5, an auxiliary capacitance is formed between the auxiliary capacitor electrode 13a and the pixel electrode 14a with the gate insulating film 21 sandwiched therebetween. In addition, as shown in (5) of FIG. 6, on the top layer of the terminal section 19, an ITO (IZO) film is formed as a protection film.

The active matrix substrate 10 is manufactured through the above-described steps. This manufacturing method includes the steps of: (i) removing, in a region where each of the terminal sections 19 is to be formed in a non-display region (peripheral region) in the active matrix substrate 10, at least a part of a gate insulating film GI (first interlayer insulating layer) deposited on a gate metal film (first metal film), followed by depositing a source metal film (second metal film) so as to form a plurality of source wirings (signal wirings) (Step (2)); and (ii) etching, in the display region, a passivation film Pas (second interlayer insulating layer) deposited on the plurality of source wirings (signal wirings) and a semiconductor layer (i layer) so that the passivation film Pas and the semiconductor layer (i layer) have a same pattern except a part of a drain electrode 16a (i.e., the part corresponding to the region 16b) of each of the TFTs 15 (Step (4)). Therefore, in the active matrix substrate 10 manufactured according to the present method, the passivation film Pas and the semiconductor layer (i layer) have the same pattern in the display region except the region 16b.

The above-described Step (2) makes it possible to bring the gate metal film and the source metal film into a direct contact so as to be electrically connected with each other. Therefore, according to the manufacturing method of the present invention, particularly in a case where an active matrix substrate is manufactured through five or less photolithography steps, the contact size between the gate metal film and the source metal film can be decreased in comparison with conventional arrangements having no other choice for the gate metal film and the source metal film but to be electrically connected by interposing a conductive material, such as a pixel electrode material, therebetween.

Moreover, in accordance with the above-described Step (4), only the gate insulating film GI is provided between the auxiliary capacitor electrode 13a made of the gate metal film and the pixel electrode 14. Consequently, the distance between the auxiliary capacitor electrode and the pixel electrode can be decreased, thereby improving the capacitance efficiency per area. This makes it possible to reduce the area of the auxiliary capacitor electrode in comparison with the conventional arrangements, thereby resulting in that the decrease in the aperture ratio of the pixel electrode can be restrained.

Now, a comparison is made between the manufacturing method of the present invention for the active matrix substrate 10, shown in FIG. 1, and a manufacturing method for a conventional active matrix substrate 110, which is illustrated in FIG. 11. The following describes differences between them as a result of the comparison.

As will be understood from the comparison between FIGS. 1 and 11, the manufacturing method of the present invention and the conventional manufacturing method are different in the layers to be etched in the photolithography steps (2) and (4).

That is, in the photolithography step (2) in the manufacturing method of the present invention, the semiconductor layer (n⁺ layer and i layer) and the gate insulating film (GI) are etched and removed. On the other hand, in the photolithography step (2) in the conventional manufacturing method, only the semiconductor layer (n⁺ layer and i layer) is etched and removed.

Moreover, the present invention and the conventional technique differ in pattern formation in the photolithography steps (2). As illustrated in (2) of FIG. 4, (2) of FIG. 5, and (2) of FIG. 6, in the manufacturing method of the present invention, the photo mask used in the step (2) is configured such that the resist 50 is formed on the entire surface of the display region so that the aperture is formed in the resist only at a part of a region where the terminal section 19 is to be formed. The semiconductor layer (n⁺ layer and i layer) and the gate insulating film (GI) are removed only at the part of the terminal section 19 where the aperture is formed. Thus, the semiconductor layer (n⁺ layer and i layer) is left on the entire surface of the display region of the active matrix substrate 10.

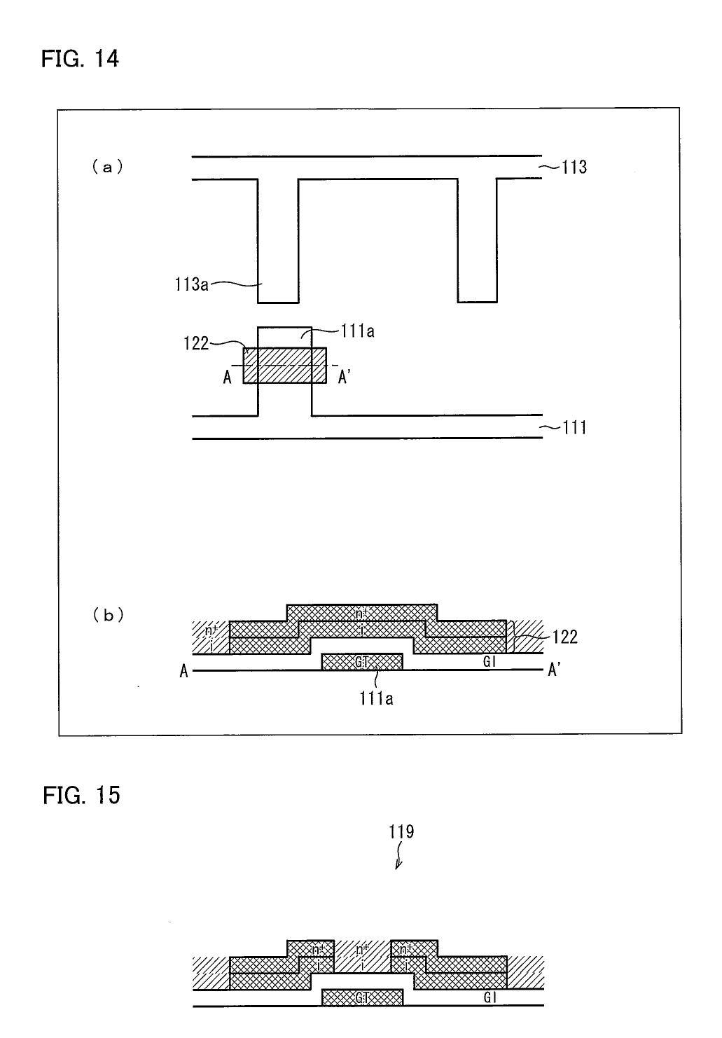

In contrast, according to the conventional manufacturing method, as illustrated in (a) and (b) of FIG. 14, pattern formation in a display region of the active matrix substrate 110 is carried out in such a manner that a semiconductor layer (n⁺ layer and i layer) 122 is left to cover a part of a gate electrode 111a but entirely removed elsewhere. Furthermore, as illustrated in FIG. 15, in a frame region of the active matrix substrate 110, a photo mask is used so that an aperture is formed in a resist only at a part of a region where a terminal section 19 is to be formed. The semiconductor layer (n⁺ layer and the i layer) is removed at the part of the terminal section 119 where the aperture is formed.

Here, (a) of FIG. 14 is a plan view of a partial structure of an active matrix substrate 110 manufactured in accordance with the conventional manufacturing method, illustrating that the active matrix substrate 110 has been patterned by the photolithography step (2). (b) of FIG. 14 is a cross sectional view illustrating a structure of the active matrix substrate 110 taken along the line A-A′ in (a) of FIG. 14. As shown in (a) of FIG. 14, as of the completion of the photolithography step (2), a gate wiring 111, a gate electrode 111a, an auxiliary capacitor wiring 113, and an auxiliary capacitor electrode 113a, which are made of a gate metal film (GT), have been formed. In addition, a semiconductor layer (n⁺ layer and i layer) 122 has been formed so as to cover a part of the gate electrode 111a.

FIG. 15 is a cross sectional view illustrating a structure of a terminal section of the active matrix substrate 110 manufactured by the conventional manufacturing method, showing that the active matrix substrate 110 has been patterned by the photolithography step (2).

In the manufacturing method of the present invention, the passivation film (Pas) and the semiconductor layer (only the i layer) are removed by the first etching performed in the photolithography step (4). Then, the source metal film (only the Al layer) is etched and removed by the second etching. As a result, the Al layer remaining at the terminal section 19 as well as the Al layer at the region 16b are removed. Thus, in the first etching, the pattern formation of the passivation film (Pas) and the semiconductor layer (only the i layer) is carried out, and in the second etching, the pattern formation of the terminal section 19 and the contact hole for electrically connecting the pixel electrode and the drain electrode is performed. It is noted that the second etching can be omitted by selecting, for example, Cr or the like as a material for the source metal film.

In contrast, in the conventional manufacturing method, the passivation film (Pas) and the gate insulating film (GI) at the region where the terminal section 119 is formed are removed by the first etching in the photolithography step (4). Then, the source metal film (only the Al layer) is etched and removed by the second etching. As a result, the Al layer left at the region where the terminal section 119 is formed as well as the Al layer in a region where a contact hole (not illustrated) is to be formed in the TFT are removed.

In the conventional manufacturing method, the semiconductor layer (i layer) is not removed by the first etching. This is because the i layer has already been etched by the etching in the photolithography step (2).

The following describes a first difference between the active matrix substrates manufactured by the manufacturing method of the present invention and by the conventional manufacturing method.

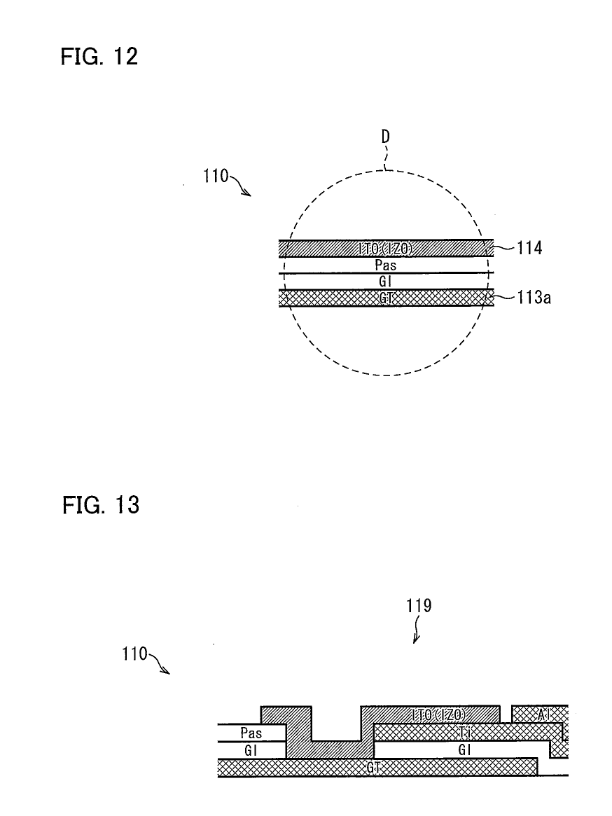

In the conventional active matrix substrate 110, as shown in FIG. 12, a double-layer insulating layer (i.e., a gate insulating film (GI) and a passivation film (Pas)) is provided between an auxiliary capacitor electrode 113a and a pixel electrode 114 that form an auxiliary capacitance. In FIG. 12, a circled region D represents a region where an auxiliary capacitance is formed by the auxiliary capacitor electrode 113a and the pixel electrode 114. In the conventional manufacturing method, the passivation film (Pas) and the gate insulating film (GI) are simultaneously removed in the fourth photolithography step. Therefore, in the region where the auxiliary capacitance is formed, there is no other choice but to leave both the passivation film (Pas) and the gate insulating film (GI) without removing these films.

Meanwhile, in the active matrix substrate 10 of the present invention, the circled region C in FIG. 8 is the region where the auxiliary capacitance is formed. As shown in FIG. 8, the auxiliary capacitance is formed between the auxiliary capacitor electrode 13a, which is formed of a protrusion of the auxiliary capacitor wiring 13, and the opposing pixel electrode 14, which is provided so as to face the auxiliary capacitor electrode 13a via the gate insulating film 21.

This arrangement is attainable due to the fact that, in the manufacturing method of the present invention, the passivation film can be formed so as to have a different pattern from that of the gate insulating film.

Therefore, the arrangement is such that only one type of insulating layer (i.e., the gate insulating layer) is provided between the both electrodes that form the auxiliary capacitance. Accordingly, in comparison with the conventional arrangement, the distance between these electrodes can be decreased, thereby accomplishing higher capacitance efficiency per area. This enables to make the area of the auxiliary capacitor electrode required for securing the capacitance relatively small and to restrain the decrease in aperture ratio of the pixel electrode.

Next is described a second difference between the structures of the active matrix substrates manufactured by the manufacturing method of the present invention and by the conventional manufacturing method.

In the present invention, the terminal section 19, which is formed in the frame region of the active matrix substrate 10, electrically connects the gate metal film and the source metal film. As shown in (a) of FIG. 9, the gate metal film and the source metal film are in direct contact with each other so that they are electrically connected with each other at the terminal section 19.

On the other hand, in the conventional active matrix substrate 110, the terminal section 119 (specifically, the connection section between the source metal film (Al, Ti) and the gate metal film (GT)) is provided for the same purpose as the above. As illustrated in FIG. 13, the terminal section 119 is structured such that the source metal film and the gate metal film are electrically connected via a transparent conductive material (ITO or IZO), which is a material of the pixel electrode.

As will be understood from a comparison between FIGS. 10 and 13, in the active matrix substrate 10 of the present invention, it is possible to decrease the contact size in comparison with that in the conventional structure. Therefore, with the present invention, it is possible to decrease the area of the peripheral region (also referred to as “frame region”) of the display panel, thereby realizing an advantageous structure for a size reduction of the device.

The manufacturing method of the present invention for manufacturing an active matrix substrate is a method for manufacturing the active matrix substrate by performing five photolithography steps. In this manufacturing method, in a second photolithography step, after a first interlayer insulating layer and a semiconductor layer have been deposited, the first interlayer insulating layer and the semiconductor layer are left unetched in a display region, while the first interlayer insulating layer and the semiconductor layer are patterned by etching in the region where the each of the terminal sections is to be formed. In addition, in a fourth photolithography step, photolithography is carried out in such a manner that, in a region where the TFTs are to be formed, a second interlayer insulating layer deposited on the signal wirings and the semiconductor layer have a same pattern except a contact hole part formed in the second interlayer insulating layer.

In the conventional manufacturing method disclosed in Patent Literature 1, the gate insulating film is not etched, and only the semiconductor layer is etched so as to form a pattern thereon. Therefore, it is impossible to bring the first metal film and the second metal film into direct contact at the terminal section.

In contrast, in the above-described manufacturing method of the present invention, in the second photolithography step, the first interlayer insulating layer (e.g., a gate insulating layer) and the semiconductor layer (e.g., an n⁺ layer and an i layer) are left unetched in the display region. Meanwhile, the first interlayer insulating layer and the semiconductor layer (the n⁺ layer and the i layer) are patterned by etching in the region where the each of the terminal sections is to be formed.

As a result, the first metal film and the second metal film are brought into direct contact with each other so as to be electrically connected with each other, thereby decreasing the contact size.

Furthermore, in the conventional manufacturing method described in Patent Literature 1, the passivation film and the gate insulating film are etched in the fourth photolithography step.

On the other hand, in the above-described manufacturing method of the present invention, in the fourth photolithography step, photolithography is performed in such a manner that, in the region where TFT is provided, the second interlayer insulating layer (e.g., a passivation film) and the semiconductor layer are patterned in an approximately same shape.

As described above, the manufacturing method according to the present invention for manufacturing an active matrix substrate includes the steps of: (i) removing, in a region where each of the terminal sections is to be formed, at least a part of a first interlayer insulating layer deposited on a first metal film, followed by depositing a second metal film so as to form the plurality of signal wirings; and (ii) etching, in the display region, a second interlayer insulating layer deposited on the plurality of signal wirings and a semiconductor layer formed into the TFTs so that the second interlayer insulating layer and the semiconductor layer have a same pattern except a part of a drain section of each of the TFTs.

Moreover, as described above, in the active matrix substrate according to the present invention, each of the TFTs including: a first interlayer insulating layer and a semiconductor layer, which are deposited on a gate electrode, a source electrode and a drain electrode, each provided on the semiconductor layer; and a second interlayer insulating layer provided on the source electrode and the drain electrode, the semiconductor layer including an impurity-undoped i layer and an impurity-doped n⁺ layer, and the second interlayer insulating layer and the i layer being provided so as to have a same pattern except a part of a region where the drain electrode is provided, and each of the terminal sections being arranged such that a contact hole is provided in a same shape in the first interlayer insulating layer and the semiconductor layer so that the first metal film has direct contact with the second metal film via the contact hole so that they are electrically connected with each other.

As such, with the present invention, particularly in a case where an active matrix substrate is manufactured through a plurality of (five or less) photolithography steps, it is possible to realize an increase in aperture ratio and a decreased in frame size of a liquid crystal display device including the active matrix substrate.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

According to the present invention, in manufacturing an active matrix substrate, it is possible to attain an increase in aperture ratio and a decrease in frame size in a liquid crystal display device including the active matrix substrate. On this account, the present invention can suitably be used in manufacturing a liquid crystal display device of superior quality without increasing cost of manufacturing.

1. A method for manufacturing an active matrix substrate of a display device, the method including forming a pattern by photolithography,
the active matrix substrate including:
a plurality of scan wirings made of a first metal film;
a plurality of signal wirings made of a second metal film, provided so as to intersect the plurality of scan wirings;
TFTs provided in a vicinity of respective intersections of the plurality of scan wirings and the plurality of signal wirings;
pixel electrodes each connected to a corresponding TFT;
auxiliary capacitor electrodes made of the first metal film, provided so as to form auxiliary capacitances in cooperation with corresponding pixel electrodes therebetween; and
terminal sections provided in a peripheral region provided on a periphery of a display region of the display device,
the method comprising the steps of:
(i) removing, in a region where each of the terminal sections is to be formed, at least a part of a first interlayer insulating layer deposited on a first metal film, followed by depositing a second metal film so as to form the plurality of signal wirings; and
(ii) etching, in the display region, a second interlayer insulating layer deposited on the plurality of signal wirings and a semiconductor layer formed into the TFTs so that the second interlayer insulating layer and the semiconductor layer have a same pattern except a part of a drain section of each of the TFTs.

2. The method according to claim 1, comprising the steps of:
(a) performing patterning on the first metal film deposited on an insulating substrate so as to form the plurality of scan wirings;
(b) depositing the first interlayer insulating layer and then the semiconductor layer on the plurality of scan wirings and then performing patterning, by etching, on the first interlayer insulating layer and the semiconductor layer in the region where the each of the terminal sections is to be formed, so as to form the each of the terminal sections;
(c) depositing the second metal film on the semiconductor layer and then performing patterning, by etching, on the second metal film and the semiconductor layer so as to form the plurality of signal wirings;
(d) depositing the second interlayer insulating layer on the plurality of signal wirings and then performing patterning on the second interlayer insulating layer and the semiconductor layer in a predetermined shape; and
(e) depositing, after the step (d), a transparent conductive material film and then etching the transparent conductive material film so as to form the pixel electrodes.

3. The method according to claim 2, wherein:
in the step (b), after the first interlayer insulating layer and the semiconductor layer have been deposited, the first interlayer insulating layer and the semiconductor layer are left unetched in the display region, while the first interlayer insulating layer and the semiconductor layer are patterned by etching in the region where the each of the terminal sections is to be formed.

4. An active matrix substrate included in a display device, comprising:
a plurality of scan wirings made of a first metal film;
a plurality of signal wirings made of a second metal film, provided so as to intersect the plurality of scan wirings;
TFTs provided in a vicinity of respective intersections of the plurality of scan wirings and the plurality of signal wirings;
pixel electrodes each connected to a corresponding TFT; and
terminal sections provided in a peripheral region provided on a periphery of a display region of the display device,
each of the TFTs including:
a first interlayer insulating layer and a semiconductor layer, which are deposited on a gate electrode in this order;
a source electrode and a drain electrode, each provided on the semiconductor layer; and
a second interlayer insulating layer provided on the source electrode and the drain electrode,
the semiconductor layer including an impurity-undoped i layer and an impurity-doped n⁺ layer, and the second interlayer insulating layer and the i layer being provided so as to have a same pattern except a part of a region where the drain electrode is provided, and
each of the terminal sections being arranged such that a contact hole is provided in a same shape in the first interlayer insulating layer and the semiconductor layer so that the first metal film has direct contact with the second metal film via the contact hole so that they are electrically connected with each other.

5. The active matrix substrate according to claim 4, further comprising:
auxiliary capacitor electrodes made of the first metal film, provided so as to form auxiliary capacitances in cooperation with corresponding pixel electrodes therebetween,
the auxiliary capacitor electrodes being arranged such that only the first interlayer insulating layer is provided between the auxiliary capacitor electrodes and the corresponding pixel electrodes, thereby causing the auxiliary capacitances to be formed therebetween.

6. A liquid crystal display device comprising:
an active matrix substrate according to claim 4;
a counter substrate; and
a liquid crystal layer sandwiched between the active matrix substrate and the counter substrate.
